(19) United States
(12) Patent Application Publication
(10) Pub. No.: US 2026/0173773 A1
(43) Pub. Date: Jun. 18, 2026

(54) CONFINED PHASE-CHANGE MEMORY

(71) Applicant: COMMISSARIAT A L'ENERGIE ATOMIQUE ET AUX ENERGIES ALTERNATIVES, PARIS (FR)

(72) Inventors: Gabriele NAVARRO, GRENOBLE CEDEX 09 (FR); Guillaume BOURGEOIS, GRENOBLE CEDEX 09 (FR)

(21) Appl. No.: 19/416,870

(22) Filed: Dec. 11, 2025

(30) Foreign Application Priority Data
Dec. 18, 2024 (FR) FR2414462

(51) Int. Cl. H10N 70/20; H10B 63/10; H10N 70/00

(52) U.S. Cl. CPC H10N 70/231; H10B 63/10; H10N 70/021; H10N 70/841

(57) ABSTRACT

A confined memory cell whose active layer formed in the cavity of the dielectric material, where it is confined, is such that the active layer lines the side wall and bottom of the cavity while delimiting an inner space without active material. Such a structure offers the benefits of a confined structure, namely a lower programming current intensity than for non-confined structures, while giving the memory cell the ability to achieve multiple programming levels.

### CROSS REFERENCE TO RELATED APPLICATIONS

This application claims priority to French Patent Application No. 2414462, filed Dec. 18, 2024, the entire content of which is incorporated herein by reference in its entirety.

### FIELD

The technical field of the invention is that of resistive phase-change memories.

The present invention relates to a phase-change material memory cell as well as a manufacturing method therefor.

### BACKGROUND

Conventional Phase-Change Memories or PCMs include two electrodes and an active layer based on a chalcogenide material. Conventional PCM memories operate based on the phase transition of the chalcogenide material, induced by heating this material under the effect of specific electrical pulses generated by its two electrodes. This transition occurs between a crystalline phase, which is orderly, has low resistance and is thermodynamically stable, and an amorphous phase, which is disorderly, has high resistance and is thermodynamically unstable.

For voltages below a threshold voltage, the current flowing in the active layer of a conventional PCM memory, initialised in an amorphous state, varies little as the voltage across the electrodes increases. Indeed, PCM memory in its amorphous state is poorly conductive. At the threshold voltage, the active material is brought to its melting temperature. Melting the active material in its amorphous state is necessary to subsequently perform recrystallisation, resulting in a low-resistance crystalline state. A change of state between a low-conductivity solid state and a highly conductive state, referred to as breakdown or “switching”, therefore takes place, characterised by sudden changes in the intensity of the current flowing through the material at a voltage close to the threshold voltage. Above this threshold voltage, the active material is in a significantly more conductive liquid state, causing the current intensity to increase with voltage.

Memories based on phase-change materials, especially chalcogenides, are known for their short programming time and high endurance, affording a large number of duty cycles. Their operating mechanism is based on exciting the phase-change material, so-called active material, with an electric current to cause it to change from a highly resistive state, herein an amorphous state, to a less resistive state, herein a crystalline state, as described above.

Among existing active material memory technologies, it is known to confine this active material in a dielectric material. The active material is thus confined in a cavity. A benefit is that the programming current required to activate the memory is much lower in intensity compared to other technologies.

A drawback of such a confined structure is that it is not compatible with making a multiple-level memory. By “multi-level memory”, it is meant a memory that does not rely on a single binary state of the active material (amorphous or crystalline), but allows this material to exist in a wide variety of states between its amorphous state and crystalline state. Indeed, a confined structure does not allow the temperature gradient that propagates through the active material to be controlled by generating a current between the electrodes it connects.

Some solutions have been contemplated for implementing a multiple-level confined memory, such as flaring the cavity in which the active material is confined from bottom to top of the cavity. Such a cavity geometry, and therefore the active material filling it, induces the existence of a temperature gradient in the active material upon activating the current. The current density is indeed lower towards the edges of the cavity than at its centre. However, this flaring causes significant manufacturing uncertainties, such as shrinkage of the active material into the cavity, particularly due to its widening at the top of the cavity, especially since such a flared geometry involves a complex manufacturing process. Further, increasing the surface area of the active material at the top of the flaring requires increasing the programming current intensity to perform activation of the material. This approach therefore does not allow, or allows only to a limited extent, the benefit of a structure confined to the programming current (i.e., the benefit of requiring a lower programming current than other existing solutions).

Other solutions provide lateral confinement of the active material, for reducing the programming current, as well as a fully confined phase-change structure, while allowing some control over the temperature gradient in the active material. However, controlling this gradient is particularly difficult to perform.

There is therefore a need for a phase-change memory cell that allows for reliable programming, especially through good control of the temperature gradient in the active material, while affording activation by a programming current of comparable intensity to that for a confined structure, while being compatible with a simplified manufacturing method and with high repeatability.

### SUMMARY

An aspect of the invention offers a solution to the problems previously discussed by providing a phase-change material memory cell in which the active layer has a cavity, for reducing the electrical contact surface areas between the active material and the upper and lower electrodes, thereby affording more precise control of the temperature gradient in the active layer.

A first aspect of the invention relates to a memory cell comprising:
a dielectric layer in which a cavity is formed, including a side wall and a bottom wall;
a memory layer, so-called active layer, made of phase-change material, lining the side wall and the bottom wall;
a lower electrode in contact with the active layer lining the bottom wall of the cavity;
an arrangement of upper electrodes including at least one upper electrode, the arrangement of upper electrodes being in contact with the active layer lining the side wall of the cavity.

By virtue of various aspects of the invention, it is possible to have a phase-change memory cell that retains the benefits of a confined structure (i.e., reduced programming current compared to known methods) while affording fine control of the temperature gradient in the active layer, especially making it possible to achieve intermediate programming levels. Such a memory cell therefore makes it possible, for example, to make a multi-level memory in a confined structure.

In the solution provided, the active layer is formed on the walls of the cavity so that its thickness is less than the dimensions of the cavity, meaning that the active layer does not fill the entire volume of the cavity but only a portion of this volume. For example, the active layer has a substantially constant thickness across all the walls of the cavity.

Thus, reducing the volume of active material in the cavity and forming the active layer on the side wall and bottom wall significantly reduces the electrical contact surface areas of the active layer with the electrodes, especially with the lower electrode (commonly called the “heater”), which leads to a reduction in the current intensity required to activate the active material. As a result, the propagation of the phase-change front under the effect of the temperature gradient when the programming current is generated is more gradual, allowing for fine control of the position of this phase-change front. It is then possible to control more precisely the temperature gradient applied to the active material and therefore the state in which it is, so as to achieve one or more intermediate states between its amorphous state and its crystalline state. In other words, the invention gives access to a gradual and controlled growth of the phase change of the active material, due to the fact that the active material lines the side wall and the bottom wall.

In particular, the invention provided, especially due to its dimensions, makes it possible to dispense with one of the drawbacks of confined structures, which is that the temperature induced by the programming current is substantially homogeneous in the active material. This homogeneous temperature field results from the fact that the current density in the active layer is uniform. This is why the temperature gradient cannot be controlled in a confined structure of the state of the art, and therefore it is not possible to control the phase-change front of the active material.

It is also noteworthy that the solution provided significantly reduces the volume of the active layer, as well as the electrical contact surface areas with the lower and upper electrodes. As a result, the volume that the active layer can occupy in the cavity is no longer dependent on the dimensions of the lower electrode. In other words, it is now possible to use a lower electrode whose dimensions, especially its width, are significantly smaller than those of a lower electrode of the state of the art. Typically, it is now possible to use a lower electrode with a width of less than 1 mm. As a result, the manufacture of the lower electrode becomes independent of that of the confined active layer.

Further, the reduction in contact surface areas and in the volume of the confined active material makes it possible to reduce the size of the memory cell, especially in comparison with known confined memories, and thus to increase the density of memory cells in a system comprising such memories.

Further to the characteristics just discussed, the memory cell according to the first aspect of the invention may have one or more additional characteristics from among the following, considered individually or according to all technically possible combinations.

In an embodiment, the electrical contact between the lower electrode and the active layer lining the bottom wall defines a first contact surface area, and the electrical contact between the arrangement of upper electrodes and the active layer lining the side wall defines a second contact surface area, the first surface area being strictly smaller than the second contact surface area.

Having a larger electrical contact surface area between the active layer and the upper electrode than between the active layer and the lower electrode ensures that the current density is higher in the active layer at the contact with the lower electrode than at the contact with the upper electrode. The phase-change front in the active material is thus generated solely from the lower electrode, ensuring the symmetrical course of this front, and therefore of the temperature gradient, in the active layer lining the side wall.

In an embodiment, the arrangement of upper electrodes comprises at least two upper electrodes, each of the two upper electrodes being in contact with a side zone of the active layer lining the side wall.

In an embodiment, the side wall of the cavity comprises a first side wall portion and a second side wall portion, the active layer lining the side wall forming a first part on the first side wall portion and a second part on the second side wall portion, and wherein the arrangement of upper electrodes comprises a first upper electrode and a second upper electrode, each of the first and second upper electrodes being in electrical contact with the first part of the active layer and the second part of the active layer, respectively.

One drawback of confined structures is that it is difficult to re-establish contact with the active material, especially because the materials used to form the active layer are significantly sensitive to chemical operations, such as chemical polishing, venting, etc. The manufacturing steps leading to re-establishing contact are therefore complex and restrictive in order to avoid damaging the active layer, while presenting a risk of degrading its behaviour in the amorphous and/or crystalline phase.

The embodiments provided here therefore circumvent these drawbacks by no longer providing horizontal electrical contact between the active layer and the upper electrode, but instead providing lateral contact, especially by virtue of the presence of the first and second upper electrodes. Such a structure is therefore much easier to manufacture than known confined structures and makes it easy to re-establish contact with the active layer lining the side wall, even when these are small in size, typically between 1 nm and 5 nm wide.

In an embodiment, the active layer lining the side wall of the cavity is in electrical contact with a same upper electrode of the arrangement of upper electrodes, with the electrical contact being made on an upper zone of the active layer lining the side wall of the cavity.

This alternative embodiment allows horizontal contact to be re-established on the upper surface of the active layer lining the side wall.

In an embodiment, the cavity has a flared shape, widening from the lower electrode to the arrangement of upper electrodes, or a right-angled parallelepiped shape.

Assuming a flared shape for the cavity facilitates the manufacture of the memory cell, compared to having a right-angled parallelepiped-shaped cavity. However, a flared cavity occupies more space than a right-angled parallelepiped cavity, thereby reducing the density of memory cells that can be simultaneously manufactured and/or used in a memory.

In an embodiment, a dielectric layer is formed on the active layer.

This filling with dielectric material ensures electrical insulation of the space delimited by the active layer, which lines the side wall and the bottom wall, while fully confining the active layer.

Another aspect of the invention relates to a structure of phase-change memory cells comprising one or more memory cells according to the first aspect.

Another aspect of the invention relates to a method for manufacturing a memory cell comprising:
providing an assembly comprising a lower electrode confined in a dielectric material;
depositing a dielectric layer onto the assembly provided;
forming a cavity in the dielectric layer, the cavity opening onto the lower electrode, the cavity comprising a side wall and a bottom wall;
depositing a so-called active layer, of phase-change material;
depositing a dielectric layer;
removing the second dielectric layer and part of the active layer so that the active layer only lines the side wall and bottom wall of the cavity, the active layer lining the bottom wall being in contact with the lower electrode;
making an arrangement of upper electrodes, comprising at least one upper electrode, the arrangement of upper electrodes being in electrical contact with the active layer lining the side wall of the cavity.

Further to the benefits provided by the structure of the memory cell itself for its manufacture, it is possible, via this method, to manufacture the memory cell described above quickly and easily. It is to be noted that it is the particular structure of this memory cell that allows such simplified manufacture, compared to prior art methods. In particular, the structure of the memory cell as defined above allows simplified re-establishment of contact with the confined active layer. Typically, the active layer can be deposited onto the lower electrode, which is not the case for memory cells of prior art, for which the lower electrode is formed under the active layer once this active layer has been formed and confined in the dielectric layer. There is therefore no risk of material shrinkage with the manufacturing method provided, especially for the active layer.

Finally, the particular structure of the memory cell makes it possible to separate the manufacture of the lower electrode from the manufacture of the confined memory, and in particular makes it possible to significantly reduce the dimensions of the lower electrode, thereby simplifying manufacture of the memory cell.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 is a schematic representation of a memory cell according to an embodiment of the invention.

FIG. 2 is a schematic representation of a memory cell according to an alternative embodiment of the invention.

FIG. 3 is a schematic representation of a memory cell according to another alternative embodiment of the invention.

FIG. 4 is a schematic representation of a memory cell according to another alternative embodiment of the invention.

FIG. 5 is a schematic representation of a memory cell according to another alternative embodiment of the invention.

FIG. 6 is a schematic representation of a memory cell according to another alternative embodiment of the invention.

FIG. 7 is a block diagram describing the sequence of steps in a method for manufacturing a memory cell according to one embodiment of the invention.

FIGS. 8 to 13 are schematic representations of a memory cell according to the invention during its manufacture by the implementation of the method of FIG. 7.

### DETAILED DESCRIPTION

Unless otherwise specified, a same element appearing in different figures has a single reference.

According to an embodiment of the invention, a memory cell is a confined cell and its active layer is only deposited against the walls of the cavity of the dielectric material, where it is confined. The active layer therefore does not fill the entire space of the cavity. Such a structure offers the benefits of a confined structure, namely a lower programming current intensity than for non-confined structures, while giving the memory cell the ability to achieve multiple programming levels. This is referred to as a multiple-level memory cell.

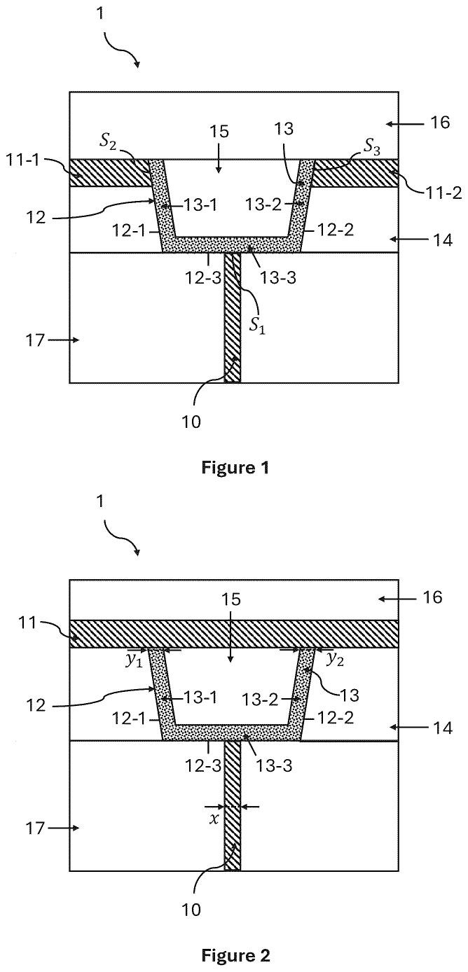

To this end, as illustrated by the embodiment in FIG. 1, the memory cell 1 according to the invention comprises a lower electrode 10, also referred to as a “heater”, an arrangement of upper electrodes comprising, for example, at least two electrodes, herein a first upper electrode 11-1 and a second upper electrode 11-2, as well as an active layer 13 confined within a first dielectric layer 14 (made of dielectric material, for example SiO₂ or SiN). In general, the lower electrode 10 is located beneath the first dielectric layer 14, and the arrangement of upper electrodes (herein the first and second upper electrodes 11-1 and 11-2) is located above the first dielectric layer 14. The upper and/or lower electrodes may be in contact with the first dielectric layer 14.

The term “confined” means that the active layer 13 is formed in an enclosure made of insulating material, herein the first dielectric layer 14, and that this active layer 13 is not in contact with the external environment, only with the lower and upper electrodes.

The active layer 13 is formed of a phase-change material, also referred to as an “active material”. This is a material that has the ability to change from an amorphous state to a crystalline state under the action of an electric current, typically flowing from the lower electrode 10 to the arrangement of upper electrodes through the active material in question. The active material is, for example, a chalcogenide such as GeSbTe, SbTe, GeTe, GaSbTe or GeSbTeSe, with possible doping (for example: In, Se, As, Ga, Ge, N, O, S, Al or Ti doping).

As mentioned previously, the active layer 13 is located in a cavity 12 formed in the first dielectric layer 14. The active layer 13 has the feature of being deposited only onto the side wall (or even side walls) as well as onto the bottom wall 12-3 of the cavity 12. The active layer 13 thus lines the side wall and the bottom wall 12-3 of the cavity. The cavity 12 is therefore not completely filled with the active material. In other words, another cavity is formed in the active layer 13. The bottom wall 12-3 of the cavity 12 is, for example, at least formed by a layer of dielectric material, so-called third dielectric layer 17, which comprises the lower electrode 10. The third dielectric layer 17 is made of dielectric material, for example SiO₂ or SiN.

In general, the arrangement of upper electrodes is in contact with the active layer that coats or lines the side wall of the cavity, while the lower electrode is in contact with the active layer that coats or lines the bottom wall of the cavity.

In particular, the side wall may, for example, comprise a first side wall portion 12-1 and a second side wall portion 12-2 which the active layer coats. Thus, the active layer 13 may be formed on the first side wall portion 12-1, on the second side wall portion 12-2 as well as on the bottom wall 12-3 of the cavity 12.

The active layer 13 thus comprises a first part 13-1 which coats (or lines) the first wall portion 12-1. The first part 13-1 is in electrical contact with the arrangement of upper electrodes. The first part 13-1 thus forms a first electrical connection with the arrangement of upper electrodes.

The active layer 13 also comprises a second part 13-2 which lines the second wall portion 12-2. The second part 13-2 is in electrical contact with the arrangement of upper electrodes. The second part 13-2 thus forms a second electrical connection with the arrangement of upper electrodes.

In other words, the first and second parts of the active layer 13 each have electrical contact with the arrangement of upper electrodes.

The electrical contact of the active layer 13 with the arrangement of upper electrodes is therefore non-common for the first part 13-1 and for the second part 13-2. That is to say, the electrical contact of the first part 13-1 with the arrangement of upper electrodes is not common (i.e., it is distinct) with the electrical contact of the second part 13-2 with the arrangement of upper electrodes. These two electrical contacts are therefore dissociated from each other.

The active layer 13 also comprises a third part 13-3 which coats the bottom wall 12-3. The third part 13-3 is in electrical contact with the lower electrode 10. The third part 13-3 thus forms a second electrical connection with the lower electrode 10.

In the embodiment of FIG. 1, the first upper electrode 11-1 is in electrical contact with the first part 13-1, and the second upper electrode 11-2 is in electrical contact with the second part 13-2. By way of example, the arrangement of upper electrodes may be arranged on the first dielectric layer 14, i.e., the first and second upper electrodes are formed on the first dielectric layer 14.

Beneficially, as illustrated in FIG. 1, each of the two upper electrodes 11-1, 11-2 may be in contact with a side zone of the active layer 13 lining the side wall of the cavity. In particular, the first and second upper electrodes 11-1 and 11-2 may be such that the electrical contact between the active layer 13 and each of these upper electrodes 11-1 and 11-2 is a lateral contact. Typically, the first upper electrode 11-1 may be in lateral electrical contact with the first portion 13-1, and the second upper electrode 11-2 may be in lateral electrical contact with the second portion 13-2.

In other words, the electrical contact of the first and second upper electrodes 11-1 and 11-2 with the first and second parts of the active layer 13 is made on a side zone of each of the first and second parts of the active layer. For each of the first and second parts, the side zone is located on the region of the active layer part in question that is at least partly in contact with the side wall of the cavity on which it is formed.

Herein, in the example of FIG. 1, the first and second upper electrodes 11-1 and 11-2 are on either side of the cavity 12, i.e., on either side of the first and second parts of the active layer 13 lining the side wall.

In an exemplary embodiment, the first and second upper electrodes are such that the side zones of contact with the first and second parts of the active layer are each as an extension of the first and second portions of the side zone of the cavity 12, respectively.

In an embodiment, the electrical contact surface area between the active layer 13 and the lower electrode 10 is strictly less than the electrical contact surface area between the active layer 13 and the arrangement of upper electrodes.

Put another way, the electrical contact between the lower electrode 10 and the active layer coating the bottom wall 12-3 (for example, the third part 13-3 of the active layer 13) defines (i.e., delimitates) a first contact surface area S₁, represented in FIG. 1. Likewise, the electrical contacts between the arrangement of upper electrodes (herein, the first and second upper electrodes) and the active layer coating the side wall of the cavity (e.g., the first and second parts of the active layer 13) on the side wall of the cavity 12 define (i.e., delimit) a second contact surface area. In the example of FIG. 1, the second surface herein corresponds to the sum of the electrical contact surface area S₂ between the first upper electrode 11-1 and the first part 13-1, and the electrical contact surface area S₃ between the second upper electrode 11-2 and the second part 13-2. In this embodiment, the first contact surface area is then strictly less than the second contact surface area (equal to S₂+S₃). In other words, the current density at the first surface area, of a current passing through the active layer 13 from the lower electrode 10 to the arrangement of upper electrodes, is strictly greater than the current density at the second surface area.

In an embodiment, the active layer 13 is conformally deposited in the cavity 12, i.e., on the first wall portion 12-1, the second wall portion 12-2 and the bottom wall 12-3. The active layer 13 therefore has a same thickness throughout the entire cavity 12.

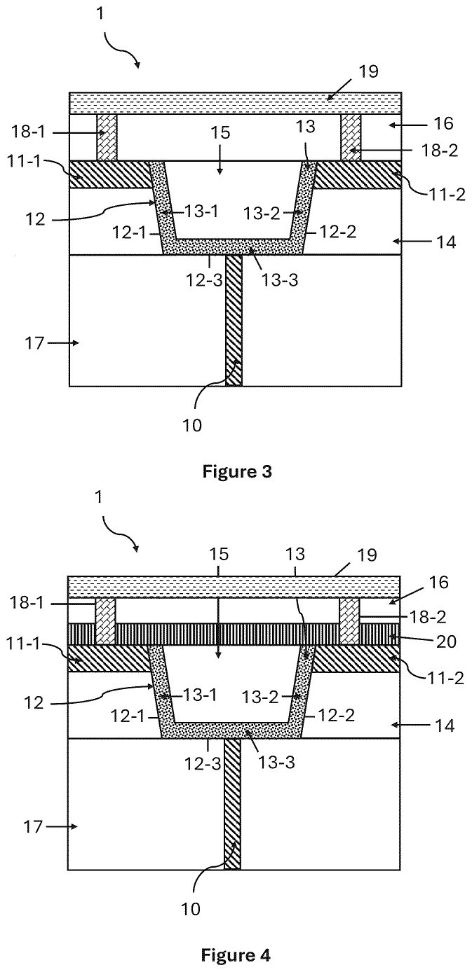

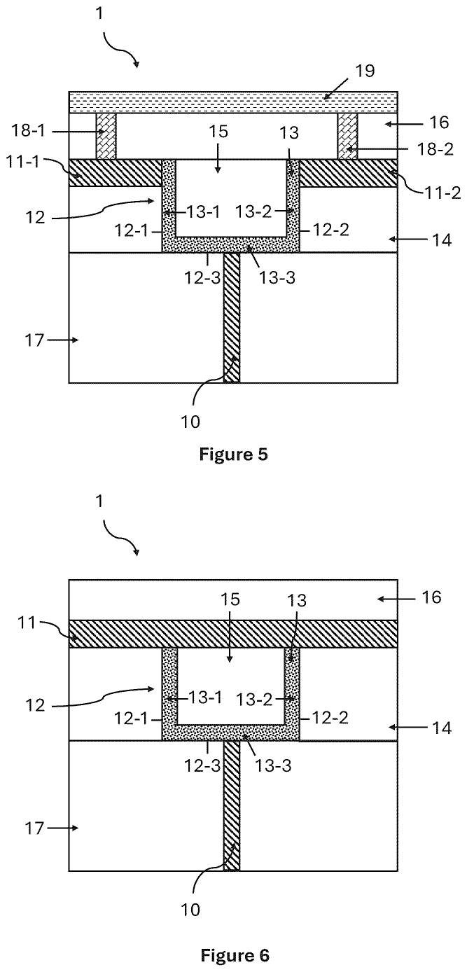

In an embodiment, illustrated in FIGS. 3 and 5, contact with the first and second upper electrodes 11-1 and 11-2 is re-established by vias formed above the first and second upper electrodes 11-1 and 11-2 and extending to these upper electrodes 11-1 and 11-2.

For example, a second dielectric layer 16 may be formed on the arrangement of upper electrodes (i.e., on the first and second upper electrodes). A first via 18-1 and a second via 18-2 may be formed in the second dielectric layer 16 so as to be in electrical contact with the arrangement of upper electrodes. In particular, the first and second vias may be formed on either side of the cavity 12. That is to say, the first via 18-1 may allow contact to be re-established with the first upper electrode 11-1, which is in electrical contact with the first part 13-1, while the second via 18-2 may allow contact to be re-established with the second upper electrode 11-2, which is in electrical contact with the second part 13-2. These vias therefore emerge from the second dielectric layer 16 at the upper electrodes.

In this alternative embodiment, a metal layer 19 may be deposited onto the second dielectric layer 16 in order to re-establish contact with the vias, for example at their top. The first and second vias then emerge from the second dielectric layer 16 at the metal layer 19 in order to be in electrical contact with this metal layer 19. The metal layer is, for example, made of a metal alloy comprising copper and manganese.

It is noted that, in this alternative embodiment, the second dielectric layer 16 may also be on the active layer 13, since the arrangement of upper electrodes may not be on this active layer 13.

The second dielectric layer is made of dielectric material, for example, SiO₂ or of SiN.

The first and second vias may be made of a conductive material such as a metal.

In an alternative embodiment illustrated in FIG. 4, a protective layer 20 made of an anti-oxidant material is formed on the arrangement of upper electrodes. The second dielectric layer 16 is then deposited onto the protective layer 20, and the first and second vias then open through the protective layer 20 to re-establish contact with the upper electrodes 11-1 and 11-2, as described hereinbefore. The protective layer 20 may be, for example, of SiN or GeN.

In an embodiment, illustrated in FIG. 2, the memory cell has the same characteristics and structure as the memory cell in the previous embodiment, except for the arrangement of the upper electrodes. Indeed, in this embodiment of FIG. 2, the arrangement of upper electrodes comprises a same upper electrode 11, and the active layer 13 lining the side wall of the cavity 12 (typically, the first and second parts 13-1 and 13-2 of the active layer 13) is in electrical contact with this same upper electrode 11. Typically, this electrical contact is made from above, and not laterally, with this same upper electrode 11.

In other words, in this embodiment, the first and second parts of the active layer 13 are in electrical contact with the same upper electrode, and the electrical contact is made on an upper zone of each of the first and second parts. The upper zone of each of the first and second parts is located on the region of the active layer part in question that is at the top of the cavity 12.

It should therefore be noted that the second contact surface area herein corresponds to the sum of the contact surface area between the first part 13-1 and the upper electrode 11 and the contact surface area between the second part 13-2 and a same upper electrode 11.

In this embodiment, the difference between the first surface area and the second surface can only depend on the difference between the width of the lower electrode, noted x, and the width of each of the first and second parts of the active layer 13, noted y₁ and y₂, respectively (illustrated in FIG. 2). This is especially the case when the depth of the active layer 13, in the direction orthogonal to the plane in which memory cell 1 is depicted in FIG. 1, is the same as the depth of the lower electrode 10, along this same direction. In this case, the width of the lower electrode is strictly less than the sum of the widths of the first and second parts of the active layer 13 (i.e., x<(y₁+y₂)). In the case where y₁=y₂, there is x<2y, with y=y₁+y₂.

In an embodiment, a dielectric layer 15 is formed on the active layer. In other words, the space between the first and second parts of the active layer is partially or completely filled with the layer of dielectric material.

This dielectric layer is made of dielectric material, for example, SiO₂ or SiN.

In an embodiment, a layer of anti-oxidant material is formed on the active layer 13, for example between the active layer 13 and the dielectric layer 15.

The layer of anti-oxidant material is, for example, conformally deposited.

The anti-oxidant material is, for example, SiN.

In an embodiment, as illustrated in FIGS. 1 to 4, the cavity 12 has a flared shape, widening from the lower electrode to the arrangement of upper electrodes (i.e., the same upper electrode 11 or the first and second upper electrodes 11-1 and 11-2). That is to say, the flared shape is wider towards the top of the cavity 12, i.e., at the arrangement of upper electrodes, and narrower towards the bottom wall 12-3 of this cavity 12, i.e., at the lower electrode 10.

In an alternative embodiment, the cavity 12 is not flared but is instead right-angled parallelepipedal in shape, as illustrated in FIGS. 5 and 6. The first and second side wall portions (as well as the first and second active layer portions) are then parallel to each other.

In an embodiment, the first contact surface area has a width between 1 nm and 10 nm, for example between 1 nm and 5 nm.

In an embodiment, the second contact surface area has a width between 1 nm and 10 nm.

In an alternative embodiment, the contact surface area of the first part 13-1 with the arrangement of upper electrodes is of the same dimensions as the contact surface area of the second part 13-2 with the arrangement of upper electrodes. Each of these surface areas is then between 0.5 nm and 5 nm.

In an embodiment, the cavity 12 has a width between 30 nm and 40 nm. That is, the distance between the first wall portion 12-1 and the second wall portion 12-2 is between 30 nm and 40 nm, over all or part of the height of the cavity. In one alternative embodiment, this width is measured at the bottom wall 12-3 or at the top of the cavity.

In an embodiment, the distance between the first part 13-1 and the second part 13-2 is between 32 and 38 nm, or even between 20 nm and 30 nm, over part or all of the height of the cavity. In an alternative embodiment, this width is measured at the base of the parts, i.e., at the bottom wall 12-3, or at the top of the parts, i.e., at the top of the cavity. The two parts of the active layer 13 are therefore at least 20 nm apart.

Another aspect of the invention relates to a structure of phase-change memory cells. This structure comprises one or more memory cells 1, as described hereinbefore. These memory cells are, for example, arranged in parallel to each other or in a matrix configuration.

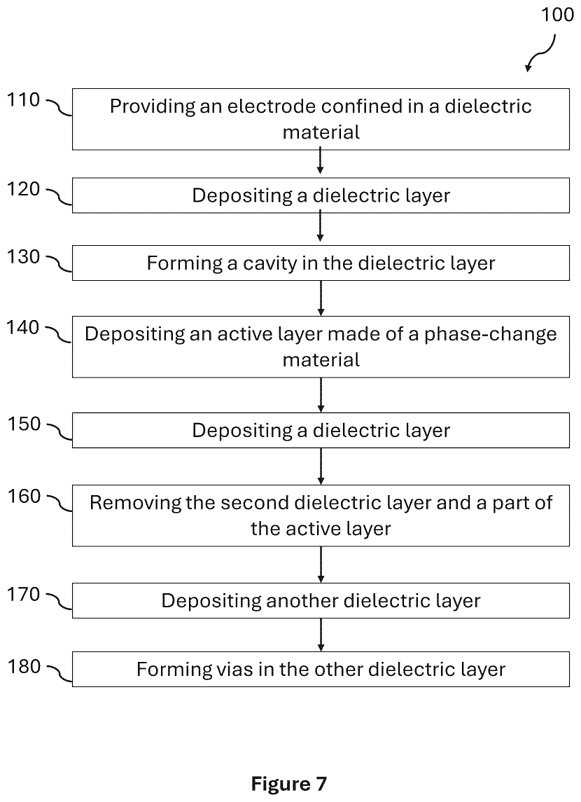

Another aspect of the invention relates, in connection with FIG. 7, to a method 100 for manufacturing the memory cell 1 described hereinbefore.

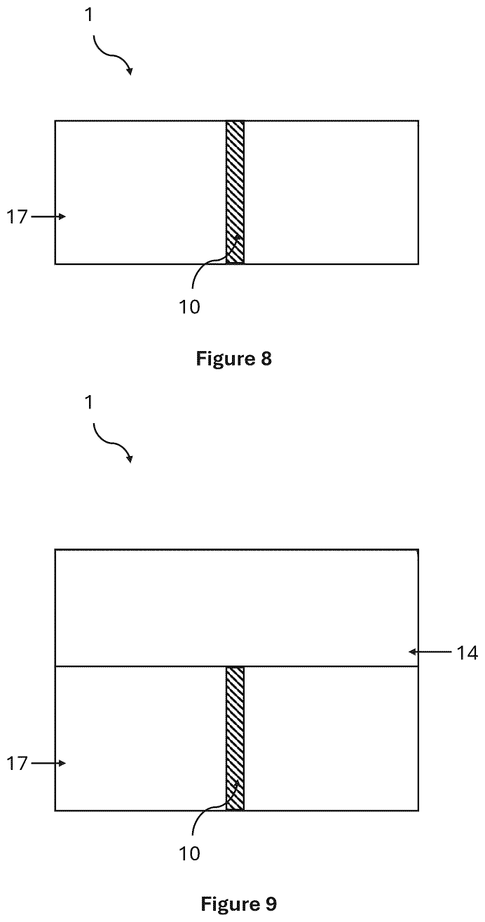

As illustrated in FIG. 7, the method 100 comprises, in connection with FIG. 8, a step 110 of providing an assembly comprising at least one lower electrode 10, which is confined in a dielectric material (typically in the third dielectric layer 17). The assembly formed by the dielectric material confining the lower electrode 10 is, for example, obtained via a known technique prior to the implementation of the method 100.

The method 100 may also comprise, in connection with FIG. 9, a step 120 of depositing a dielectric layer, typically corresponding to the first layer 14 described hereinbefore, onto the assembly provided, i.e., on the dielectric material in which the at least one lower electrode 10 is confined.

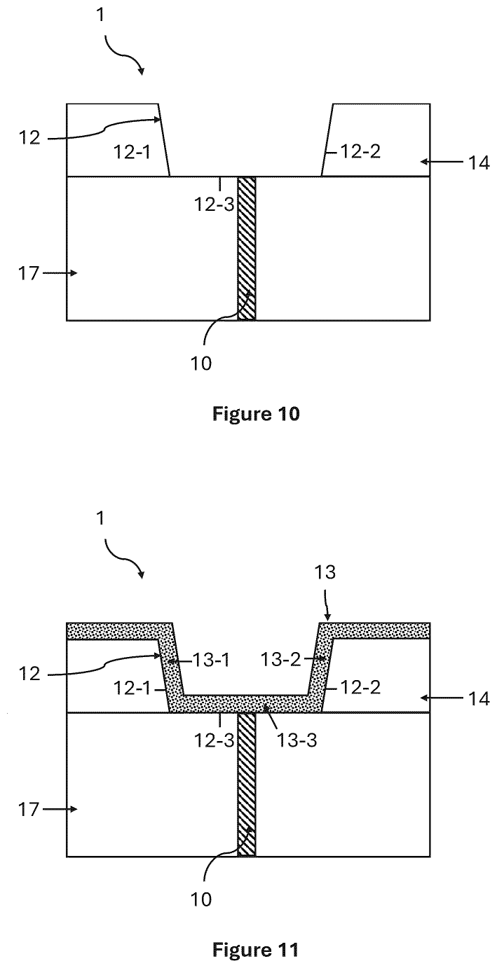

The method 100 also comprises, in connection with FIG. 10, a step 130 of forming the cavity 12. The cavity 12 is formed in the dielectric layer deposited so as to open onto the lower electrode.

The method 100 also comprises, in connection with FIG. 11, a step 140 of depositing the active layer 13.

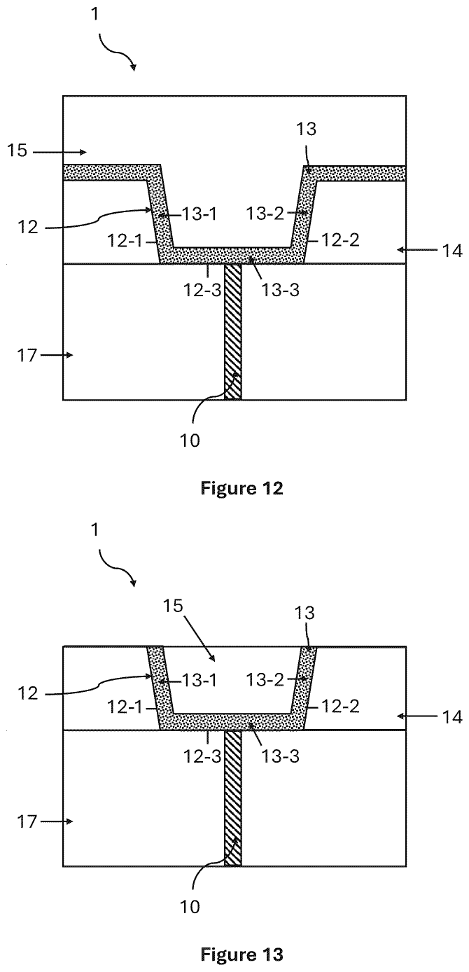

The method 100 also comprises, in connection with FIG. 12, a step 150 of depositing the dielectric layer 15.

The method 100 also comprises, in connection with FIG. 13, a step 160 of removing the dielectric layer 15 as well as part of the active layer 13, so that the active layer 13 only coats (or lines) the side wall and bottom wall of the cavity 12. The removal is therefore carried out, for example by etching and/or mechanical-chemical polishing, for example until the active layer 13 retains the first part 13-1 coating the first portion of the side wall 12-1, the second part 13-2 coating the second side wall portion 12-2 and the third part 13-3 coating the bottom wall 12-3 of the cavity 12. It is reminded that the third part 13-3 (i.e., the active layer lining the bottom wall of the cavity) is in electrical contact with the lower electrode 10.

The method 100 also includes a step of making the arrangement of upper electrodes. This arrangement is made such that the at least one upper electrode it comprises is in electrical contact with the active layer coating the side wall of the cavity (e.g., to be in contact with the first and second parts of the active layer 13).

For example, this arrangement of upper electrodes is made such that it comprises the first and second upper electrodes 11-1 and 11-2, described hereinbefore and in connection with FIG. 1, or such that it comprises a same upper electrode 11 in contact with the active layer, as described hereinbefore in connection with FIG. 2.

In one embodiment, the method 100 also comprises a step 170 of depositing another dielectric layer, for example in SiO₂, typically corresponding to the second dielectric layer 16 described hereinbefore, in connection with FIGS. 1 and 2.

In one embodiment, the method 100 also comprises, in connection with FIG. 3, a step 180 of forming vias, especially the first and second vias in the other dielectric layer deposited (i.e., the second dielectric layer 16). These vias are formed so as to be in electrical contact with the first and second upper electrodes 11-1 and 11-2, on either side of the cavity 12. These vias therefore emerge from the other dielectric layer deposited, at the arrangement of upper electrodes.

In one alternative embodiment, the step 180 of forming the vias also includes depositing the metal layer 19 onto the other dielectric layer deposited so as to re-establish contact with the vias, especially the first and second vias. These first and second vias herein open through this other dielectric layer at the metal layer 19 to allow this contact re-establishment.

In one embodiment, in connection with FIG. 4, the method 100 also includes a step of depositing the protective layer 20 onto the arrangement of upper electrodes. The protective layer 20 is deposited before the other dielectric layer (i.e., the second dielectric layer 16) is deposited, and this other dielectric layer is deposited onto the protective layer 20. Thus, the vias are also formed through the protective layer 20.

In one embodiment, the method 100 also comprises a step of depositing the layer of anti-oxidant material onto the active layer 13. The dielectric layer 15 is then deposited onto the layer of anti-oxidant material, and the removal step 160 also comprises removing the layer of anti-oxidant material so that the active layer 13 retains only the first, second and third parts.

It is noted that, although the method 100 is described for the manufacture of a memory cell, it can definitely be used to manufacture a plurality of memory cells 1 in parallel, especially to form the structure of phase-change memory cells.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components, processes or structures described herein. This is merely for convenience and to give a general sense of the processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A memory cell comprising:
a dielectric layer in which a cavity is formed, including a side wall and a bottom wall;
a memory layer, forming an active layer, made of phase-change material, lining the side wall and the bottom wall
a lower electrode in contact with the active layer lining the bottom wall of the cavity;
an arrangement of upper electrodes including at least one upper electrode, the arrangement of upper electrodes being in contact with the active layer lining the side wall of the cavity;
wherein the arrangement of upper electrodes comprises at least two upper electrodes, each of the two upper electrodes being in contact with a side zone of the active layer lining the side wall.

2. The memory cell according to claim 1, wherein the electrical contact between the lower electrode and the active layer lining the bottom wall defines a first contact surface area, and the electrical contact between the arrangement of upper electrodes and the active layer lining the side wall defines a second contact surface area, the first surface area being strictly smaller than the second contact surface area.

3. The memory cell according to claim 2, wherein the side wall of the cavity comprises a first side wall portion and a second side wall portion, the active layer lining the side wall forming a first part on the first side wall portion and a second part on the second side wall portion, and wherein the arrangement of upper electrodes comprises a first upper electrode and a second upper electrode, each of the first and second upper electrodes being in electrical contact with the first part of the active layer and the second part of the active layer, respectively.

4. The memory cell according to claim 1, wherein the cavity has a flared shape, widening from the lower electrode to the arrangement of upper electrodes, or a right-angled parallelepiped shape.

5. The memory cell according to claim 1, wherein a dielectric layer is formed on the active layer.

6. A structure of phase-change memory cells comprising one or more memory cells according to claim 1.

7. A method for manufacturing a memory cell, the method comprising:
providing an assembly comprising a lower electrode confined in a dielectric material;
depositing a dielectric layer onto the assembly provided;
forming a cavity in the dielectric layer, the cavity opening onto the lower electrode, the cavity comprising a side wall and a bottom wall;
depositing an active layer, made of phase-change material;
depositing a dielectric layer;
removing the second dielectric layer and a part of the active layer so that the active layer only lines the side wall and bottom wall of the cavity, the active layer lining the bottom wall being in contact with the lower electrode;
making an arrangement of upper electrodes, the arrangement of upper electrodes being in electric contact with the active layer lining the side wall of the cavity, the arrangement of upper electrodes comprising at least two upper electrodes, each of the two upper electrodes being in contact with a side zone of the active layer lining the side wall.
